(19) United States
(12) Patent Application Publication
(10) Pub. No.: US 2023/0375918 A1
(43) Pub. Date: Nov. 23, 2023

(54) PHOTOSENSITIVE RESIN COMPOSITION, PHOTOSENSITIVE RESIN FILM USING SAME, COLOR FILTER AND DISPLAY DEVICE

(71) Applicant: SAMSUNG SDI CO., LTD., Yongin-si, Gyeonggi-do (KR)

(72) Inventors: Sohyun KIM, Suwon-si, Gyeonggi-do (KR); Sangho LEE, Suwon-si, Gyeonggi-do (KR); Juho JUNG, Suwon-si, Gyeonggi-do (KR)

(21) Appl. No.: 18/031,398

(22) PCT Filed: May 3, 2022
(86) PCT No.: PCT/KR2022/006318

§ 371 Date: Apr. 12, 2023

(30) Foreign Application Priority Data
Jun. 11, 2021 (KR) 10-2021-0075929

(51) Int. Cl. G03F 5/20; C08K 5/10; C08K 5/33; C08K 5/00; C08K 5/37; C08K 5/544; C08K 5/5435; C08K 5/5419; C08K 5/02; C08F 136/22

(52) U.S. Cl. CPC G03F 5/20; C08K 5/10; C08K 5/33; C08K 5/0041; C08K 5/37; C08K 5/544; C08K 5/5435; C08K 5/5419; C08K 5/02; C08F 136/22

(57) ABSTRACT

Provided are a photosensitive resin composition including (A) a binder resin; (B) a photopolymerizable compound; (C) a photopolymerization initiator; (D) a colorant including a blue pigment; (E) a solvent; (F) a thiol-based compound; and (G) a silane coupling agent; wherein the thiol-based compound and the silane coupling agent are each independently included in an amount of greater than or equal to 0.1 wt % and less than 0.3 wt % based on based on the total amount of the photosensitive resin composition, a photosensitive resin film manufactured using the photosensitive resin composition, a color filter including the photosensitive resin film, and a display device including the color filter.

### TECHNICAL FIELD

This disclosure relates to a photosensitive resin composition, a photosensitive resin film manufactured using the same, a color filter including the photosensitive resin film, and a display device including the color filter.

### BACKGROUND ART

A liquid crystal display among many kinds of displays has an advantage of lightness, thinness, low cost, low power consumption for operation, and improved adherence to an integrated circuit and has been more widely used for a laptop computer, a monitor, and a TV screen. This liquid crystal display is equipped with a color filter formed by repeating a unit pixel, in which three primary color sub-pixels of red (R), green (G), and blue (B) are combined. The unit pixel displays a particular color due to a combination of three primary colors when each sub-pixel is adjacently disposed and then, applied by a color signal and controlled about brightness.

The color filter is made of red (R), green (G), and blue (B) color dyes or pigments. These color materials play a role of changing a white light from a backlight unit into each corresponding color light. Color characteristics are improved as the spectrum of the color material has no unnecessary wavelengths other than the required absorption wavelength and has a narrow absorption band. In addition, it should have excellent heat resistance, light resistance, and chemical resistance that does not fade or change color under ultraviolet, acid, and base conditions exposed during the etching process of the color resist.

However, securing photoresist stability against moisture is emerging as a new problem as panel makers' requirements for maintaining close-contacting force with a substrate and preventing the generation of sublimable foreign substances in a harsh environment of high temperature and high humidity have increased.

### DISCLOSURE

### Technical Problem

An embodiment provides a photosensitive resin composition capable of suppressing generation of sublimable foreign substances, minimizing peeling problems, and securing pattern properties even in harsh environments of high temperature and high humidity.

Another embodiment provides a photosensitive resin film manufactured using the photosensitive resin composition.

Another embodiment provides a color filter including the photosensitive resin film.

Another embodiment provides a display device including the color filter.

### Technical Solution

An embodiment of the present invention provides a photosensitive resin composition including (A) a binder resin; (B) a photopolymerizable compound; (C) a photopolymerization initiator; (D) a colorant including a blue pigment; (E) a solvent; (F) a thiol-based compound; and (G) a silane coupling agent; wherein the thiol-based compound and the silane coupling agent are each independently included in an amount of greater than or equal to 0.1 wt % and less than 0.3 wt % based on based on the total amount of the photosensitive resin composition.

The thiol-based compound and the silane coupling agent may be included in a weight ratio of 1:1 to 2:1.

The thiol-based compound may include at least two or more functional groups represented by Chemical Formula 1 at the terminal end.

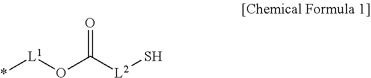

In Chemical Formula 1,

L¹ and L² are each independently a single bond, a substituted or unsubstituted C1 to C20 alkylene group, a substituted or unsubstituted C3 to C20 cycloalkylene group, a substituted or unsubstituted C6 to C20 arylene group, or a substituted or unsubstituted C2 to C20 heteroarylene group.

The thiol-based compound may be represented by Chemical Formula 1-1.

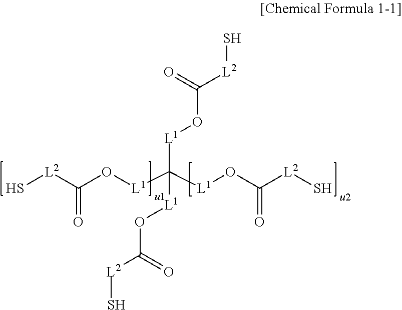

In Chemical Formula 1-1,

L¹ and L² are each independently a single bond, a substituted or unsubstituted C1 to C20 alkylene group, a substituted or unsubstituted C3 to C20 cycloalkylene group, a substituted or unsubstituted C6 to C20 arylene group, or a substituted or unsubstituted C2 to C20 heteroarylene group, and

u1 and u2 are each independently an integer of 0 or 1.

The silane coupling agent may be an amino-based silane coupling agent.

The amino-based silane coupling agent may be represented by Chemical Formula 2.

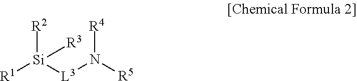

In Chemical Formula 2,

R¹ to R³ are each independently a hydrogen atom, a substituted or unsubstituted C1 to C20 alkyl group, or a substituted or unsubstituted C1 to C20 alkoxy group,

R⁴ and R⁵ are each independently a hydrogen atom, a substituted or unsubstituted C1 to C20 alkyl group, or a substituted or unsubstituted C6 to C20 aryl group, and

L³ is a substituted or unsubstituted C1 to C20 alkylene group.

The binder resin may include an acrylic binder resin, a cardo-based binder resin, or a combination thereof.

The binder resin may be an acrylic binder resin, and the acrylic binder resin may have a weight average molecular weight of 5000 g/mol to 15000 g/mol.

The binder resin may be an acrylic binder resin, and the acrylic binder resin may have an acid value of 80 mgKOH/g to 130 mgKOH/g.

The photosensitive resin composition may include 5 wt % to 20 wt % of the binder resin; 1 wt % to 10 wt % of the photopolymerizable compound; 0.1 wt % to 10 wt % of the photopolymerization initiator; 5 wt % to 50 wt % of the colorant; 30 wt % to 70 wt % of the solvent; 0.1 wt % to 0.29 wt % of the thiol-based compound; and 0.1 wt % to 0.29 wt % of the silane coupling agent based on the total amount of the photosensitive resin composition.

The photosensitive resin composition may include malonic acid; 3-amino-1,2-propanediol; a leveling agent; a fluorine-based surfactant; or a combination thereof.

Another embodiment provides a photosensitive resin film manufactured using the photosensitive resin composition.

Another embodiment provides a color filter including the photosensitive resin film.

Another embodiment provides a display device including the color filter.

Other embodiments of the present invention are included in the following detailed description.

### Advantageous Effects

The photosensitive resin composition according to an embodiment may suppress production (sublimation) of sublimable foreign substances in a high-temperature and high-humidity environment and at the same time secure pattern properties.

### DESCRIPTION OF THE DRAWINGS

FIG. 1 is a photograph of a pattern manufactured from the photosensitive resin composition according to Example 1.

FIG. 2 is a photograph of a pattern manufactured from the photosensitive resin composition according to Example 2.

FIG. 3 is a pattern photograph manufactured from the photosensitive resin composition according to Comparative Example 10.

### MODE FOR INVENTION

Hereinafter, embodiments of the present invention are described in detail. However, these embodiments are exemplary, the present invention is not limited thereto and the present invention is defined by the scope of claims.

In the present specification, when specific definition is not otherwise provided, “substituted” refers to one substituted with a substituent selected from a halogen (F, Br, Cl, or I), a hydroxy group, a nitro group, a cyano group, an amino group (NH₂, NH(R²⁰⁰), or N(R²⁰¹)(R²⁰²), wherein R²⁰⁰, R²⁰¹, and R²⁰² are the same or different, and are each independently a C1 to C10 alkyl group), an amidino group, a hydrazine group, a hydrazone group, a carboxyl group, a substituted or unsubstituted alkyl group, a substituted or unsubstituted alkenyl group, a substituted or unsubstituted alkynyl group, a substituted or unsubstituted alicyclic organic group, a substituted or unsubstituted aryl group, and a substituted or unsubstituted heterocyclic group.

In the present specification, when specific definition is not otherwise provided, “alkyl group” refers to a C1 to C20 alkyl group, and specifically a C1 to C15 alkyl group, “cycloalkyl group” refers to a C3 to C20 cycloalkyl group, and specifically a C3 to C18 cycloalkyl group, “alkoxy group” refers to a C1 to C20 alkoxy group, and specifically a C1 to C18 alkoxy group, “aryl group” refers to a C6 to C20 aryl group, and specifically a C6 to C18 aryl group, “alkenyl group” refers to a C2 to C20 alkenyl group, and specifically a C2 to C18 alkenyl group, “alkylene group” refers to a C1 to C20 alkylene group, and specifically a C1 to C18 alkylene group, and “arylene group” refers a C6 to C20 arylene group, and specifically a C6 to C₁₆ arylene group.

In the present specification, when specific definition is not otherwise provided, “(meth)acrylate” refers to “acrylate” and “methacrylate” and “(meth)acrylic acid” refers to “acrylic acid” and “methacrylic acid.”

In the present specification, when a definition is not otherwise provided, the term “combination” refers to mixing or copolymerization. In addition, “copolymerization” refers to block copolymerization to random copolymerization, and “copolymer” refers to a block copolymer to a random copolymer.

In the chemical formula of the present specification, unless a specific definition is otherwise provided, hydrogen is boned at the position when a chemical bond is not drawn where supposed to be given.

In the present specification, a cardo-based resin refers to a resin including at least one functional group selected from Chemical Formula 3-1 to Chemical Formula 3-11 in a backbone.

In the present specification, when specific definition is not otherwise provided, “*” indicates a point where the same or different atom or chemical formula is linked.

An embodiment provides a photosensitive resin composition including (A) a binder resin; (B) a photopolymerizable compound; (C) a photopolymerization initiator; (D) a colorant including a blue pigment; (E) a solvent; (F) a thiol-based compound; and (G) a silane coupling agent; wherein the thiol-based compound and the silane coupling agent are each independently included in an amount of greater than or equal to 0.1 wt % and less than 0.3 wt % based on based on the total amount of the photosensitive resin composition.

In order to prevent the generation of sublimable foreign substances under high-temperature and high-humidity conditions, conventional methods of changing a surface treatment of the pigment, changing a dispersant, or the like for securing dispersion stability in pigment dispersion are used, and in addition, a silane coupling agent is introduced to improve peeling characteristics of a photoresist on a substrate, and a bottom cure-enhancing initiator or a specific photopolymerizable monomer or binder resin having sufficient close-contacting force with glass is applied to increase the close-contacting force with the substrate.

The sublimable foreign substances under the high-temperature and high-humidity conditions mainly come from the dispersant or the pigment applied in the pigment dispersion, which is caused by stability deterioration of the pigment dispersion. Since the (conventional) methods of changing the pigment or the dispersant to secure the pigment dispersion stability affect color characteristics, it is difficult to select a material satisfying all characteristics in a short period. In addition, a general silane coupling agent has an effect of enhancing the close-contacting force with the substrate but a limitation of having no effect of controlling the sublimable foreign substances.

Accordingly, the present inventors have clearly recognized the limitations of the conventional methods and thus secured polydispersity stability in the pigment dispersion by introducing an appropriate amount of the amino-based silane coupling agent and a *—NH group in a structure of the amino-based silane coupling agent through numerous trials and errors and simultaneously, satisfied peeling characteristics due to the silane group strengthening adherence between the glass and the binder resin in the photoresist.

However, the sensitivity deterioration of the amino-based silane coupling agent is difficult to overcome only by increasing a content of the photopolymerization initiator. Accordingly, the present inventors have conducted numerous studies again to confirm that the sensitivity deterioration may be overcome by applying an amplifying agent, wherein as an amount of the amplifying agent is increased, there is a problem that nonuniformity of the edge of the pattern severely occurs, and thus repeated numerous trials and errors again to finally overcome the problem of the sensitivity deterioration by controlling the amplifying agent and the amino-based silane coupling agent within specific content ranges.

Hereinafter, each component is described in detail.

(G) Silane Coupling Agent

The photosensitive resin composition according to an embodiment includes a silane coupling agent, and at this time, the silane coupling agent may be included in an amount of greater than or equal to 0.1 wt % and less than 0.3 wt % based on the total amount of the photosensitive resin composition, so that generation of sublimable foreign substances in a high-temperature and high-humidity environment and peeling issues can be solved. When the silane coupling agent is included in an amount of greater than or equal to 0.3 wt % based on the total amount of the photosensitive resin composition, CD sensitivity cannot be secured, and when the silane coupling agent is included in an amount of less than 0.1 wt % based on the total amount of the photosensitive resin composition, the content is too insignificant and it may be impossible to realize the desired effect due to the addition of the silane coupling agent. For example, the silane coupling agent may be included in an amount of 0.1 wt % to 0.29 wt % based on the total amount of the photosensitive resin composition.

For example, the silane coupling agent may be an amino-based silane coupling agent. When the silane coupling agent is not an amino-based silane coupling agent, generation of sublimable foreign substances in a high-temperature and high-humidity environment may not be suppressed or it may be difficult to solve a peeling problem.

Specifically, the amino-based silane coupling agent may refer to a silane coupling agent including a *—NR (R is a hydrogen atom or a C1 to C20 alkyl group) group, and may be represented by Chemical Formula 2.

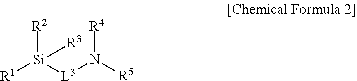

In Chemical Formula 2,

R¹ to R³ are each independently a hydrogen atom, a substituted or unsubstituted C1 to C20 alkyl group, or a substituted or unsubstituted C1 to C20 alkoxy group,

R⁴ and R⁵ are each independently a hydrogen atom, a substituted or unsubstituted C1 to C20 alkyl group, or a substituted or unsubstituted C6 to C20 aryl group, and

L³ is a substituted or unsubstituted C1 to C20 alkylene group.

For example, in Chemical Formula 2, at least one of R⁴ and R⁵ may be a hydrogen atom.

When the amino-based silane coupling agent also has a structure different from that of Chemical Formula 2, it may not be effective in suppressing generation of sublimable foreign substances and peeling in a high-temperature and high-humidity environment.

The silane coupling agent, specifically the amino-based silane coupling agent represented by Chemical Formula 2, can solve sublimable foreign substances in a high-temperature and high-humidity environment and peeling issues, but there are side effects of decreasing CD sensitivity and lowering chemical resistance, and therefore, a thiol-based compound described later should be used as an amplifying agent.

(F) Thiol-Based Compound

The photosensitive resin composition according to an embodiment includes the thiol-based compound in an amount of greater than or equal to 0.1 wt % and less than 0.3 wt % based on the total amount of the photosensitive resin composition, thereby improving side effects caused by the use of the silane coupling agent, that is, reduction in CD sensitivity and furthermore, uniformity of the pattern edge portion may be secured by controlling the content of the thiol-based compound within the above range. In addition, through the use of the thiol-based compound, it is possible to greatly reduce a curing shrinkage rate and at the same time have a great effect on preventing a decrease in luminance. When the thiol-based compound is included in an amount of greater than or equal to 0.3 wt % based on the total amount of the photosensitive resin composition, pattern uniformity cannot be secured, and when the thiol-based compound is included in an amount of less than 0.1 wt % based on the total amount of the photosensitive resin composition, the content is too insignificant and thus the desired effect may not be realized due to the addition of the thiol-based compound. For example, the thiol-based compound may be included in an amount of 0.1 wt % to 0.29 wt % based on the total amount of the photosensitive resin composition.

The thiol-based compound may have 2 to 10, for example, 2 to 4 thiol groups (—SH) at the terminal end depending on its structure.

For example, the thiol-based compound may include at least two or more functional groups represented by Chemical Formula 1 at the terminal end.

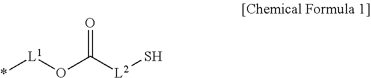

In Chemical Formula 1,

L¹ and L² are each independently a single bond, a substituted or unsubstituted C1 to C20 alkylene group, a substituted or unsubstituted C3 to C20 cycloalkylene group, a substituted or unsubstituted C6 to C20 arylene group, or a substituted or unsubstituted C2 to C20 heteroarylene group.

For example, the thiol-based compound may be represented by Chemical Formula 1-1.

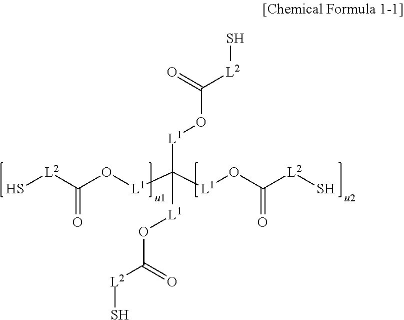

In Chemical Formula 1-1,

L¹ and L² are each independently a single bond, a substituted or unsubstituted C1 to C20 alkylene group, a substituted or unsubstituted C3 to C20 cycloalkylene group, a substituted or unsubstituted C6 to C20 arylene group, or a substituted or unsubstituted C2 to C20 heteroarylene group, and

u1 and u2 are each independently an integer of 0 or 1.

For example, in Chemical Formula 1 and Chemical Formula 1-1, L¹ and L² may each independently be a single bond or a substituted or unsubstituted C1 to C20 alkylene group.

Specific examples of the sulfur-containing compound may include any one selected from pentaerythritol tetrakis(3-mercaptopropionate) represented by Chemical Formula 1a, trimethylolpropane tris(3-mercaptopropionate) represented by Chemical Formula 1b, pentaerythritol tetrakis (mercaptoacetate) represented by Chemical Formula 1c, trimethylolpropane tris(2-mercaptoacetate) represented by Chemical Formula 1d, glycol di-3-mercaptopropionate represented by Chemical Formula 1e, and a combination thereof.

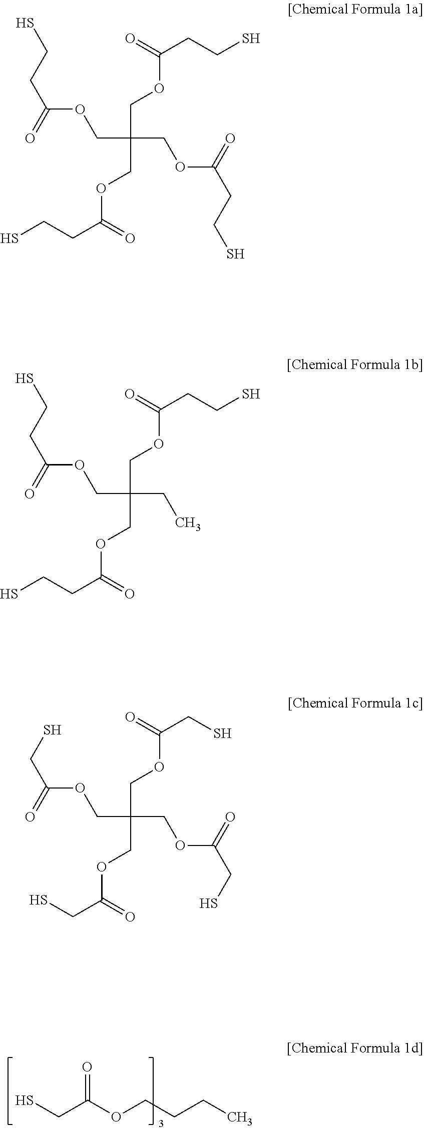

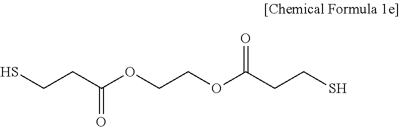 [SMILES: O=C(CCS)OCCOC(=O)CCS]

The thiol-based compound and the silane coupling agent may be included in a weight ratio of 1:1 to 2:1. When the thiol-based compound and the silane coupling agent are included in a weight ratio of 1:1 to 1:2 while being included in an amount of 0.1 wt % to 0.3 wt % based on the total amount of the photosensitive resin composition according to an embodiment, in a high-temperature and high-humidity environment, effects of suppression of generation of sublimation foreign substances, suppression of exfoliation, minimization of decrease in CD sensitivity, and improvement of chemical resistance and pattern properties may be realized at the same time.

(A) Binder Resin

The binder resin may include an acrylic binder resin, a cardo-based binder resin, or a combination thereof.

The acrylic binder resin is a copolymer of a first ethylenic unsaturated monomer and a second ethylenic unsaturated monomer that is copolymerizable therewith, and is resin including at least one acrylic repeating unit.

The first ethylenic unsaturated monomer is an ethylenic unsaturated monomer including at least one carboxyl group. Examples of the monomer include (meth)acrylic acid, maleic acid, itaconic acid, fumaric acid, or a combination thereof.

The first ethylenic unsaturated monomer may be included in an amount of 5 wt % to 50 wt %, for example 10 wt % to 40 wt % based on a total amount of the acrylic binder resin.

The second ethylenic unsaturated monomer may be an aromatic vinyl compound such as styrene, α-methylstyrene, vinyl toluene, vinylbenzylmethylether and the like; an unsaturated carboxylate ester compound such as methyl(meth)acrylate, ethyl(meth)acrylate, butyl(meth)acrylate, 2-hydroxyethyl(meth)acrylate, 2-hydroxybutyl(meth)acrylate, benzyl(meth)acrylate, cyclohexyl(meth)acrylate, phenyl(meth)acrylate, and the like; an unsaturated amino alkyl carboxylate ester compound such as 2-aminoethyl(meth)acrylate, 2-dimethylaminoethyl(meth)acrylate, and the like; a carboxylic acid vinyl ester compound such as vinyl acetate, vinyl benzoate, and the like; an unsaturated glycidyl carboxylate ester compound such as glycidyl(meth)acrylate, and the like; a vinyl cyanide compound such as (meth)acrylonitrile and the like; an unsaturated amide compound such as (meth)acrylamide, and the like; and the like, and may be used alone or as a mixture of two or more.

Specific examples of the acrylic binder resin may be a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto and these may be used alone or as a mixture of two or more. For example, the photosensitive resin composition according to the embodiment may include an acrylic binder resin.

A weight average molecular weight of the acrylic binder resin may be 5,000 g/mol to 15,000 g/mol. When the acrylic binder resin has a weight average molecular weight within the range, the photosensitive resin composition has good physical and chemical properties, appropriate viscosity, and close contacting properties with a substrate during manufacture of a color filter.

An acid value of the acrylic binder resin may be 80 mgKOH/g to 130 mgKOH/g. When the acid value of the acrylic binder resin is within the above range, the pixel pattern resolution is improved.

For example, the photosensitive resin composition according to the embodiment may be a cardo-based binder resin or a mixture of the acrylic-based binder resin and the cardo-based binder resin.

The cardo-based binder resin may be represented by Chemical Formula 3.

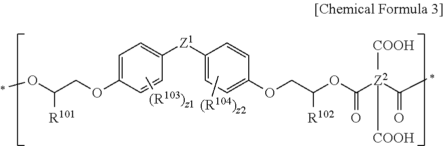

In Chemical Formula 3,

R¹⁰¹ and R¹⁰² are each independently a hydrogen atom or a substituted or unsubstituted (meth)acryloyloxy alkyl group,

R¹⁰³ and R¹⁰⁴ are each independently a hydrogen atom, a halogen atom or a substituted or unsubstituted C1 to C20 alkyl group, and

Z¹ is a single bond, O, CO, SO₂, CR¹⁰⁷R¹⁰⁸ , SiR¹⁰⁹R¹¹⁰ (wherein, R¹⁰⁷ to R¹¹⁰ are each, independently a hydrogen atom or a substituted or unsubstituted C1 to C20 alkyl group), or one of linking groups represented by Chemical Formulas 3-1 to 3-11,

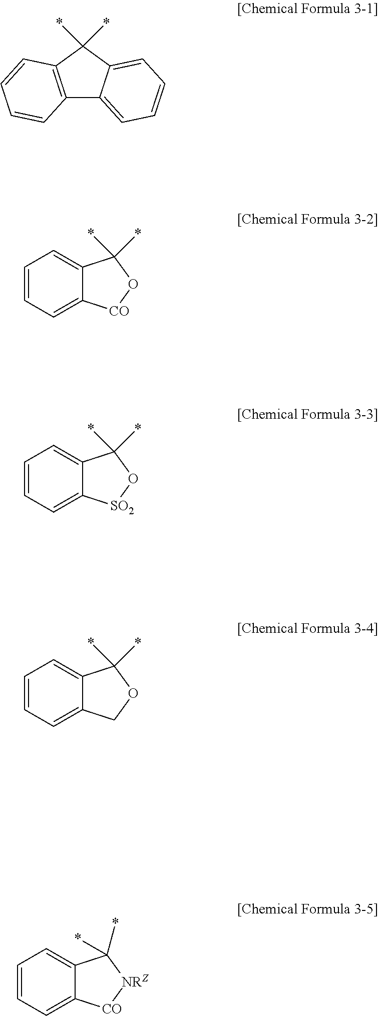

(In Chemical Formula 3-5,

R^{z} is a hydrogen atom, an ethyl group, C₂H₄Cl, C₂H₄OH, CH₂CH═CH₂, or a phenyl group.)

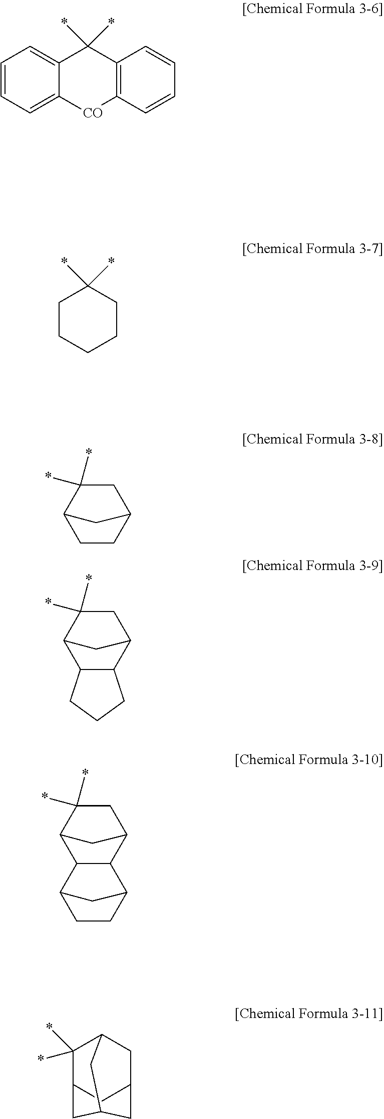

Z² is an acid anhydride moiety or acid dianhydride moiety, and

z1 and z2 are each independently an integer ranging from 0 to 4.

A weight average molecular weight of the cardo-based binder resin may be 500 g/mol to 50,000 g/mol, for example 1,000 g/mol to 30,000 g/mol. When the weight average molecular weight of the cardo-based binder resin is within the ranges, a satisfactory pattern may be formed without a residue during a manufacture of a light blocking layer and without losing a film thickness during development.

The cardo-based binder resin may include a functional group represented by Chemical Formula 4 at at least one terminal end of both terminal ends.

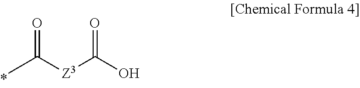

In Chemical Formula 4,

Z³ is represented by Chemical Formulas 4-1 to 4-7.

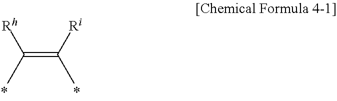

(In Chemical Formula 4-1, R^{h} and Rⁱ are each independently a hydrogen atom, a substituted or unsubstituted C1 to C20 alkyl group, an ester group, or an ether group.)

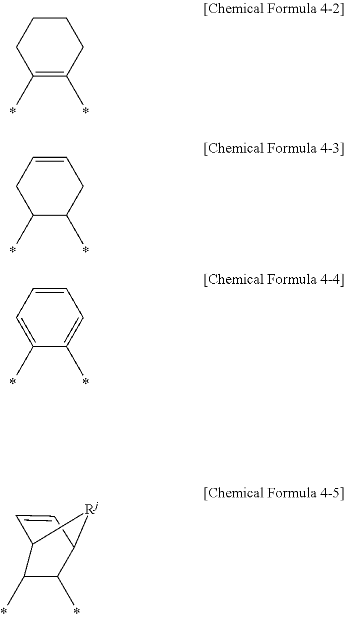

(In Chemical Formula 4-5, R is O, S, NH, a substituted or unsubstituted C1 to C20 alkylene group, a C1 to C20 alkylamine group, or a C2 to C20 alkenylamine group.)

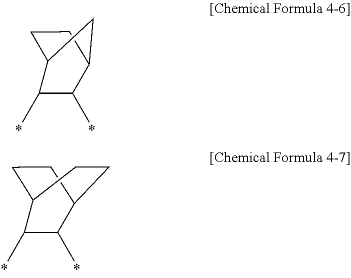

The cardo-based binder resin may be, for example prepared by mixing at least two of a fluorene-containing compound such as 9,9-bis(4-oxiranylmethoxyphenyl)fluorene, and the like; an anhydride compound such as benzenetetracarboxylic acid dianhydride, naphthalenetetracarboxylic acid dianhydride, biphenyltetracarboxylic dianhydride, benzophenonetetracarboxylic dianhydride, pyromellitic dianhydride, cyclobutanetetracarboxylic dianhydride, perylenetetracarboxylic dianhydride, tetrahydrofurantetracarboxylic dianhydride, tetrahydrophthalic anhydride, and the like; a glycol compound such as ethylene glycol, propylene glycol, polyethylene glycol, and the like; an alcohol compound such as methanol, ethanol, propanol, n-butanol, cyclohexanol, benzylalcohol, and the like; a solvent-based compound such as propylene glycol methylethylacetate, N-methylpyrrolidone, and the like; a phosphorus compound such as triphenylphosphine, and the like; an amine or ammonium salt compound such as tetramethylammonium chloride, tetraethylammonium bromide, benzyl di ethyl amine, triethylamine, tributylamine, benzyltriethylammonium chloride, and the like.

When the binder resin is a cardo-based binder resin, the solvent type curable composition including the same has excellent developability and sensitivity during photo-curing and thus, fine pattern-forming capability.

The binder resin may be included in an amount of 5 wt % to 20 wt %, for example 7 wt % to 15 wt % based on the total amount of the photosensitive resin composition. When the binder resin is included within the above range, it is possible to obtain excellent surface smoothness due to excellent developability and improved crosslinking property during manufacturing of the color filter.

(B) Photopolymerizable Compound

The photopolymerizable compound may be a monofunctional or multifunctional ester of (meth)acrylic acid having at least one ethylenically unsaturated double bond.

The photopolymerizable compound has the ethylenically unsaturated double bond and thus, may cause sufficient polymerization during exposure in a pattern-forming process and form a pattern having excellent heat resistance, light resistance, and chemical resistance.

Specific examples of the photopolymerizable compound may be ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Commercially available examples of the photopolymerizable compound are as follows. Examples of the mono-functional ester of (meth)acrylic acid may include Aronix M-101®, M-111®, M-114 (Toagosei Chemistry Industry Co., Ltd.); KAYARAD TC-110S®, TC-120S® (Nippon Kayaku Co., Ltd.); V-158®, V-2311 (Osaka Organic Chemical Ind., Ltd.), and the like. Examples of a di-functional ester of (meth)acrylic acid may include Aronix M-210®, M-240®, M-6200® (Toagosei Chemistry Industry Co., Ltd.), KAYARAD HDDA®, HX-220®, R-604® (Nippon Kayaku Co., Ltd.), V-260®, V-312®, V-335 HP® (Osaka Organic Chemical Ind., Ltd.), and the like. Examples of a tri-functional ester of (meth)acrylic acid may include Aronix M-309®, M-400®, M-405®, M-450®, M-710®, M-8030®, M-8060® (Toagosei Chemistry Industry Co., Ltd.), KAYARAD TMPTA®, DPCA-20®, DPCA-30®, DPCA-60®, DPCA-120® (Nippon Kayaku Co., Ltd.), V-295®, V-300®, V-360®, V-GPT®, V-3PA®, V-400® (Osaka Yuki Kayaku Kogyo Co. Ltd.), and the like. These may be used alone or as a mixture of two or more.

The photopolymerizable compound may be treated with acid anhydride to improve developability.

The photopolymerizable compound may be included in an amount of 1 wt % to 10 wt %, for example 3 wt % to 8 wt %. When the photopolymerizable compound is included within the range, the photopolymerizable compound is sufficiently cured during exposure in a pattern-forming process and has excellent reliability, and developability for alkali developing solution may be improved.

(C) Photopolymerization Initiator

The photopolymerization initiator is a generally-used initiator for a photosensitive resin composition, for example an acetophenone-based compound, a benzophenone-based compound, a thioxanthone-based compound, a benzoin-based compound, a triazine-based compound, an oxime-based compound, or a combination thereof.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-di chlorobenzophenone, 3,3′-dimethyl-2-methoxybenzophenone, and the like.

Examples of the thioxanthone-based compound may be thioxanthone, 2-methylthioxanthone, isopropylthioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethyl ketal, and the like.

Examples of the triazine-based compound may be 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be O-acyloxime-based compound, 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione 2-oxime-O-benzoate, 1-(4-phenylsulfanyl phenyl)-octane-1,2-dione2-oxime-O-benzoate, 1-(4-phenyl sulfanyl phenyl)-octan-1-one oxime-O-acetate, 1-(4-phenylsulfanyl phenyl)-butan-1-oneoxime-O-acetate, and the like.

The photopolymerization initiator may further include a carbazole-based compound, a diketone-based compound, a sulfonium borate-based compound, a diazo-based compound, an imidazole-based compound, a biimidazole-based compound, a fluorene-based compound, and the like, besides the compounds.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of 0.1 wt % to 10 wt %, for example 0.1 wt % to 5 wt % based on the total amount of the photosensitive resin composition. When the photopolymerization initiator is included within the range, excellent reliability may be secured due to sufficiently curing during exposure in a pattern-forming process, a pattern may have excellent resolution and close-contacting properties as well as excellent heat resistance, light resistance, and chemical resistance, and transmittance may be prevented from deterioration due to a non-reaction initiator.

(D) Colorant

The photosensitive resin composition according to an embodiment includes a colorant, and the colorant includes a blue pigment.

For example, the blue pigment may include an epsilon blue pigment. For example, the blue pigment may include “a blue-hybrid pigment of ‘the epsilon blue pigment’ and ‘a xanthene-based violet dye’” in addition to “the epsilon blue pigment.”

Herein, luminance may be more improved, compared with a case of using the xanthene-based violet dye alone. In addition, when the epsilon blue pigment is included, transmittance may be kept low in a wavelength region of 400 nm to 450 nm. In other words, blue-hybrid blue pigment dispersion in the present specification may be blue pigment dispersion prepared by mixing the xanthene-based violet dye may be mixed with blue pigment dispersion in which the epsilon blue pigment is dispersed.

For example, the epsilon blue pigment is C.I. Pigment Blue 15:6 and the like.

For example, the blue pigment may be a derivative combined with an organic polymer.

For example, the blue pigment may be included in the photosensitive resin composition in the form of pigment dispersion.

The pigment dispersion may include a solid pigment, a solvent, and a dispersant in order to disperse the pigment in the solvent uniformly.

The solid content of the pigment may be 1 wt % to 20 wt %, for example 8 wt % to 20 wt %, for example 8 wt % to 15 wt %, for example 10 wt % to 20 wt %, for example 10 wt % to 15 wt % based on the total amount of the pigment dispersion.

The dispersant may be a non-ionic dispersant, an anionic dispersant, a cationic dispersant, and the like. Specific examples of the dispersant may be polyalkylene glycol and esters thereof, polyoxyalkylene, polyhydric alcohol ester alkylene oxide addition product, an alcohol alkylene oxide addition product, sulfonate ester, sulfonate salt, a carboxylate ester, a carboxylate salt, alkylamide alkylene oxide addition product, alkyl amine, and the like, and may be used alone or as a mixture of two or more.

Commercially available examples of the dispersant may include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like made by BYK Co., Ltd.; EFKA-47, EFKA-47EA, EFKA-48, EFKA-49, EFKA-100, EFKA-400, EFKA-450, and the like made by EFKA Chemicals Co.; Solsperse 5000, Solsperse 12000, Solsperse 13240, Solsperse 13940, Solsperse 17000, Solsperse 20000, Solsperse 24000GR, Solsperse 27000, Solsperse 28000, and the like made by Zeneka Co.; or PB711, or PB821 made by Ajinomoto Inc.

The dispersant may be included in an amount of 1 wt % to 20 wt % based on a total amount of the pigment dispersion. When the dispersant is included within the range, dispersion of a photosensitive resin composition is improved due to an appropriate viscosity, and thus optical, physical and chemical quality may be maintained when the photosensitive resin composition is applied to products.

A solvent for forming the pigment dispersion may be ethylene glycol acetate, ethylcellosolve, propylene glycol methylether acetate, ethyllactate, polyethylene glycol, cyclohexanone, propylene glycol methylether, and the like.

The colorant including the blue pigment may be included in an amount of 5 wt % to 50 wt %, for example 10 wt % to 45 wt %, for example 15 wt % to 40 wt % based on the total amount of the photosensitive resin composition. When the colorant is included within the above range, it is advantageous to secure a process margin, and the color gamut and contrast ratio are improved.

Meanwhile, the colorant may further include a dye represented by Formula 5 below in addition to the blue pigment.

Since the dye represented by Chemical Formula 5 has spectral characteristics of intensively absorbing light in a very narrow region of 400 nm to 450 nm and high solubility for an organic solvent, a photosensitive resin composition including this dye as a colorant may be used to form a color filter having excellent color gamut. The very narrow region of 400 nm to 450 nm is a blue light hazard area, and the higher the transmittance in the wavelength region of 400 nm to 450 nm, the more difficult it is to realize high color coordinates (lower Bx), and the lower the transmittance in the wavelength region of 400 nm to 450 nm, the easier the high color coordinates (lower Bx) is to realize. Since the transmittance in the wavelength region of 400 nm to 450 nm is proportional to an area of a lower portion of a transmittance graph, a transmission spectrum may be checked to easily judge whether the transmittance is high or low. Furthermore, a photosensitive resin film formed of a composition including the dye represented by Chemical Formula 5 as a colorant may have high color gamut and low reflectance.

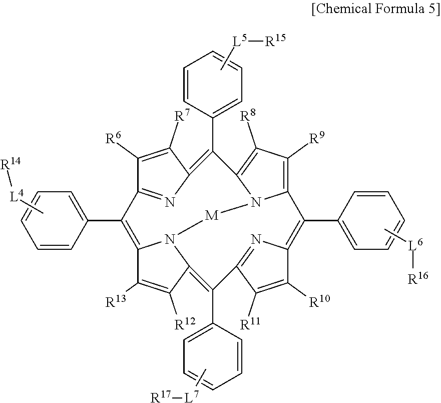

In Chemical Formula 5,

M is Cu, Co, VO, Zn, Pt, or In,

L⁴ to L⁷ are each independently *—C(═O)O—* or *—S(═O)₂NH—*,

R¹⁴ to R¹⁷ are each independently a halogen atom, a substituted or unsubstituted C1 to C20 alkyl group, substituted or unsubstituted C3 to C20 cycloalkyl group, a substituted or unsubstituted C6 to C20 aryl group, or a substituted or unsubstituted C2 to C20 heteroaryl group, and

R⁶ to R¹³ are each independently a hydrogen atom or a halogen atom.

In Chemical Formula 5, para substitution positions of substituents (*-L⁴-R¹⁴, *-L⁶-R¹⁶, and *-L⁷-R¹⁷) among ortho, meta, and para substitution positions may be advantageous to increase absorbance in the narrow wavelength region of 400 nm to 450 nm. For example, since the dye represented by Chemical Formula 1 having the substituents at the para positions exhibits very strong absorbance in the range of 400 nm to 450 nm, for example, 400 nm to 435 nm, the composition including this dye as a colorant may exhibit excellent color reproducibility, color stability, light resistance, and the like as well as have low Bx.

For example, in Chemical Formula 5, L⁴ to L⁷ may each independently be *—C(═O)O—* and the R¹⁴ to R¹⁷ may each independently be a substituted or unsubstituted C1 to C20 alkyl group. Herein, since the dye has the most excellent compatibility with the phthalocyanine-based dye, the composition has low transmittance in the wavelength region of 400 nm to 450 nm and thus may maintain low Bx and simultaneously, excellent durability.

For example, the dye represented by Chemical Formula 5 may have maximum absorption in a wavelength range of 400 nm to 435 nm.

For example, the compound represented by Chemical Formula 5 may be represented by one of Chemical Formula 5-1 to Chemical Formula 5-14, but is necessarily not limited thereto.

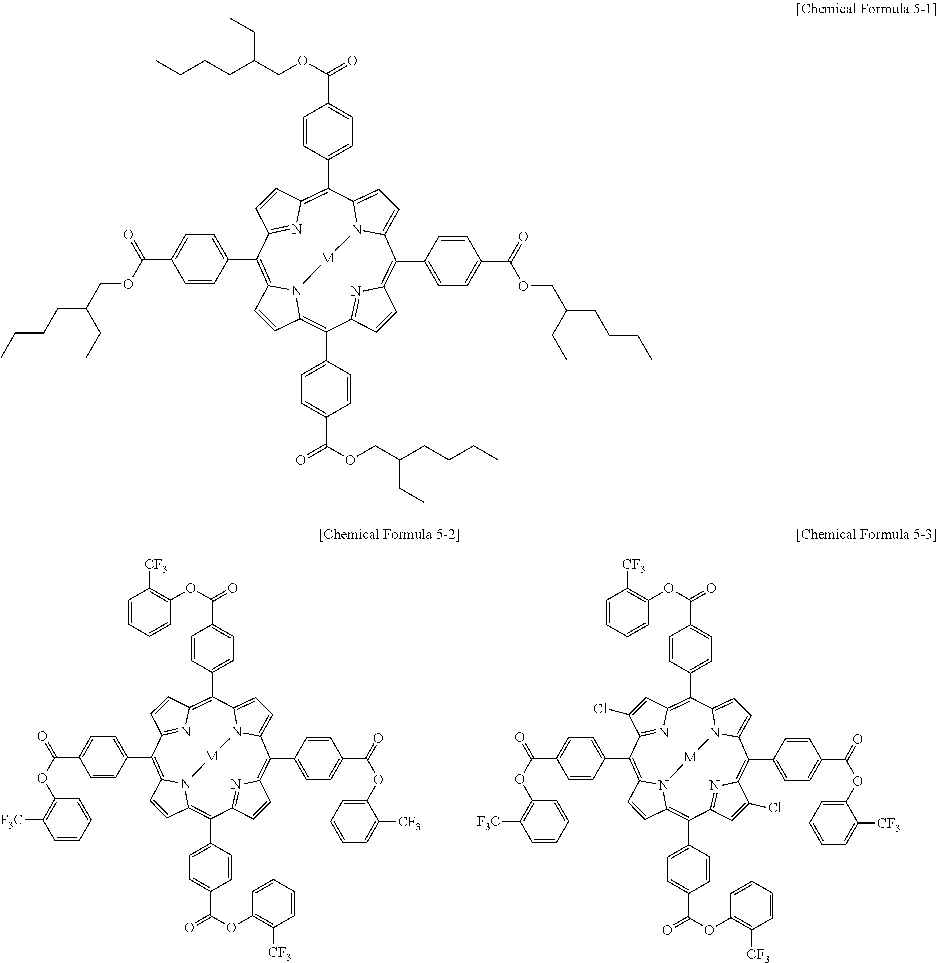

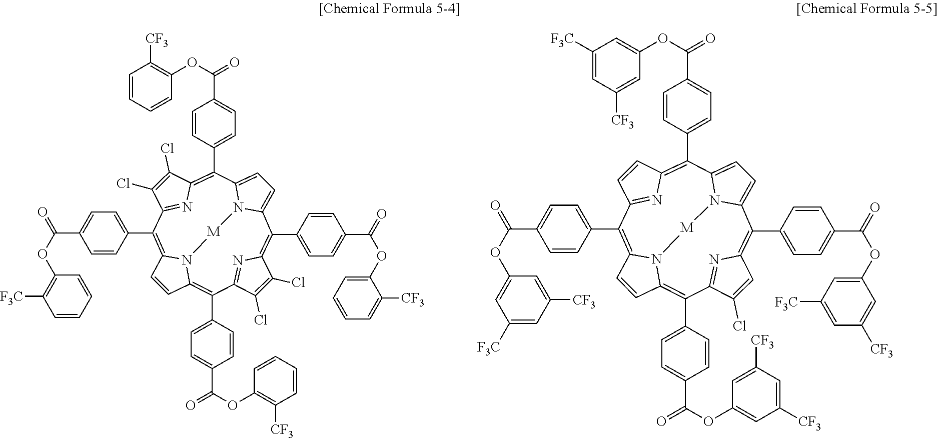

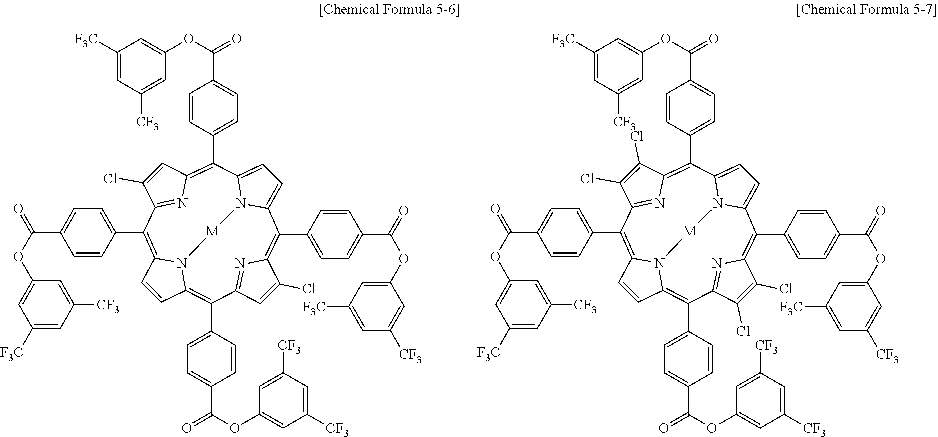

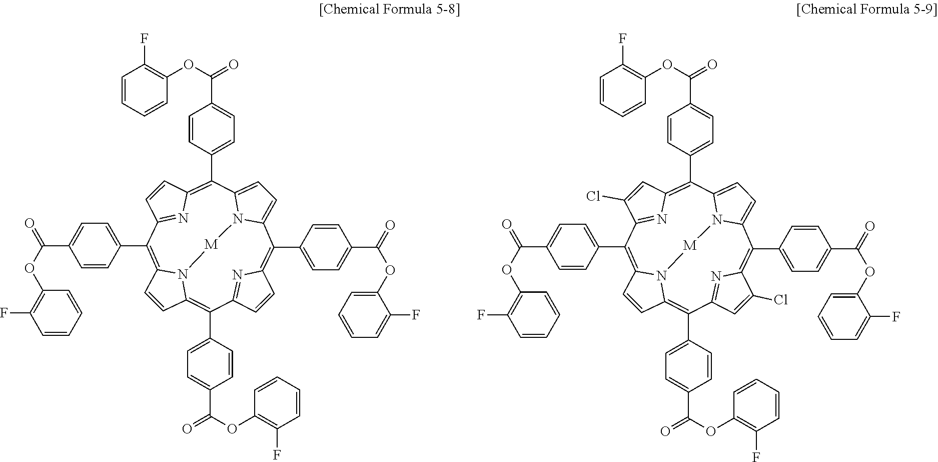

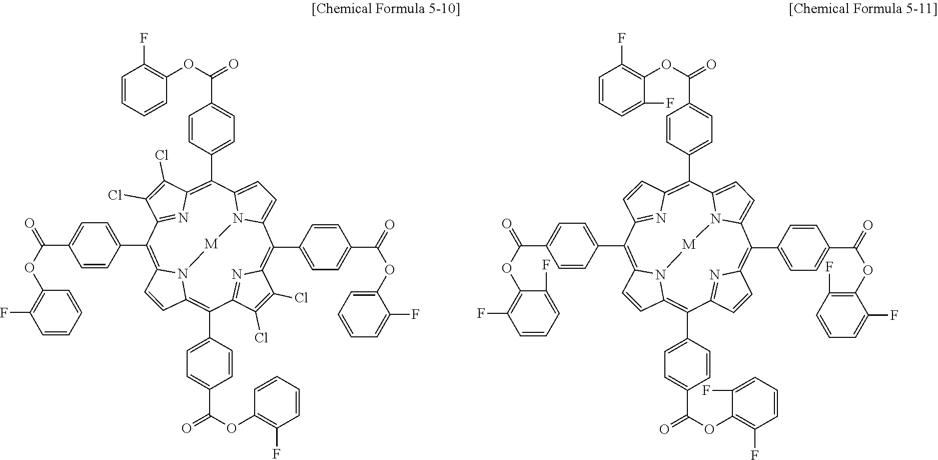

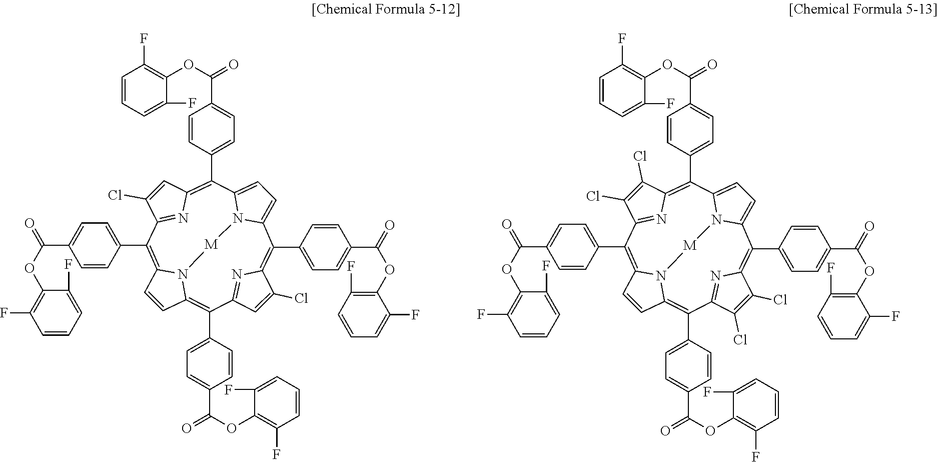

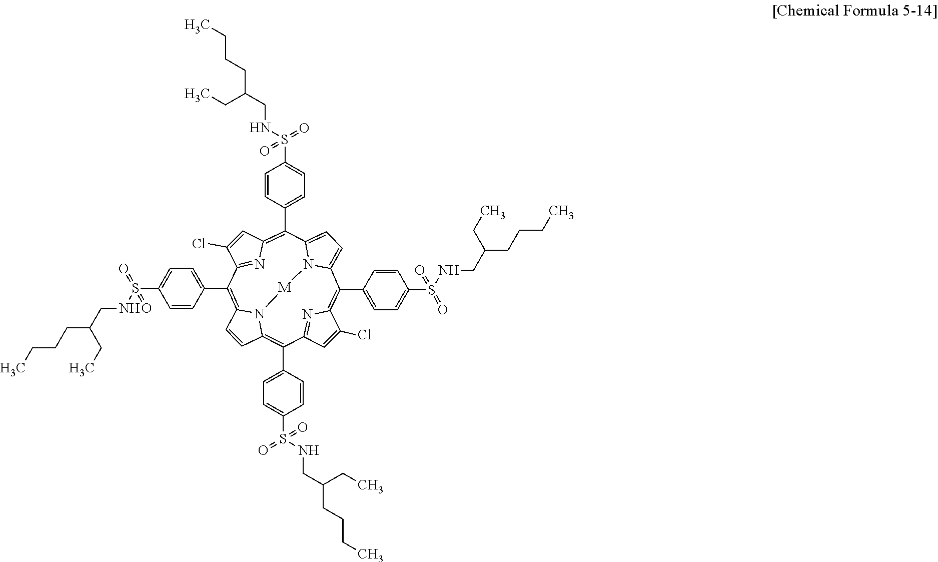

In Chemical Formula 5-1 or Chemical Formula 5-14,

M is Cu, Co, VO, Zn, Pt, or In.

For example, the dye represented by Chemical Formula 5 may be included in a smaller amount than the phthalocyanine-based dye to be described later. For example, the dye represented by Chemical Formula 5 and the phthalocyanine-based dye may be included in a weight ratio of 1:1.1 to 1:2. When this dye represented by Chemical Formula 5 is included in a smaller amount than that of the phthalocyanine-based dye and specifically, in the weight ratio (while maintaining low Bx), durability such as heat resistance, chemical resistance, and the like may be more improved.

The dye represented by Chemical Formula 5 may be included in an amount of 1 wt % to 10 wt %, for example 5 wt % to 10 wt %, based on the total amount of the photosensitive resin composition according to an embodiment.

The photosensitive resin composition according to an embodiment may further include a phthalocyanine-based dye represented by Chemical Formula 6 in addition to the blue pigment and the dye represented by Chemical Formula 5.

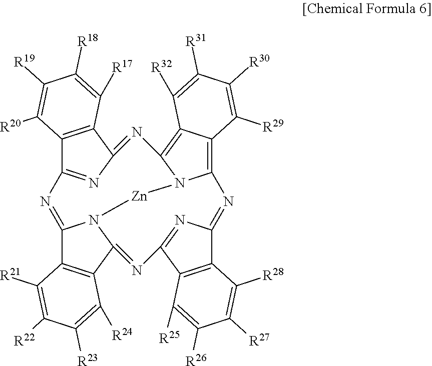

In Chemical Formula 6,

R¹⁷ to R³² are each independently a halogen atom, a substituted or unsubstituted C1 to C20 alkoxy group, or a substituted or unsubstituted C6 to C20 aryloxy group.

For example, in Chemical Formula 6, at least one of R¹⁷ to R²⁰ and at least one of R²⁵ to R²⁸ may be a C6 to C20 aryloxy group substituted with a halogen atom, and at least one of R²¹ to R²⁴ and at least one of R²⁹ to R³² may be a C6 to C20 aryloxy group substituted with a are C6 to C10 aryl group. Specifically, in Chemical Formula 6, any one of R″ and R¹⁹ and any one of R²⁶ and R²⁷ may be a C6 to C20 aryloxy group substituted with a halogen atom, and any one of R²² and R²³ and any one of R³⁰ and R³¹ may be a C6 to C20 aryloxy group substituted with a C6 to C10 aryl group. When the phthalocyanine-based dye represented by Chemical Formula 6 is as described above, it has the best compatibility with the dye represented by Chemical Formula 5, effectively improving durability such as heat resistance and chemical resistance (while maintaining a low Bx).

The phthalocyanine-based dye may be included in an amount of 5 wt % to 20 wt %, for example, 5 wt % to 15 wt %, based on the total amount of the photosensitive resin composition according to an embodiment. When included in the above range, it is possible to easily achieve high color coordinates having low transmittance in the wavelength range of 400 nm to 450 nm.

(E) Solvent

The solvent may be a material that have compatibility with the thiol-based compound, the silane coupling agent, the colorant, the binder resin, the photopolymerizable compound, and the photopolymerization initiator but does not react therewith.

Examples of the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol methylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. Additionally, high boiling point solvent such as N-methylformamide, N,N-dimethylformamide, N-methylformanilide, N-methylacetamide, N,N-dimethylacetamide, N-methylpyrrolidone, dimethylsulfoxide, benzyl ethyl ether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like may be also used.

Considering miscibility and reactivity, ketones such as cyclohexanone, glycol ethers such as ethylene glycol monoethylether, and the like; ethylene glycol alkylether acetates such as ethyl cellosolve acetate, and the like; esters such as 2-hydroxy ethyl propionate, and the like; carbitols such as diethylene glycol monomethylether, and the like; propylene glycol alkylether acetates such as propylene glycol monomethylether acetate, propylene glycol propylether acetate, and the like may be used.

The solvent may be included in a balance amount, for example 30 wt % to 70 wt %, for example 30 wt % to 60 wt %, for example 40 wt % to 70 wt % based on the total amount of the photosensitive resin composition. When the solvent is included within the range, the photosensitive resin composition may have an appropriate viscosity and thus processability is improved during a production of a color filter.

(H) Other Additives

The photosensitive resin composition according to an embodiment includes malonic acid; 3-amino-1,2-propanediol; a silane-based coupling agent containing a vinyl group or a (meth)acryloxy group; a leveling agent; a fluorine-based surfactant; or a combination thereof.

For example, the photosensitive resin composition may further include a silane-based coupling agent having a reactive substituent such as a vinyl group, a carboxyl group, a methacryloxy group, an isocyanate group, or an epoxy group in order to improve close contacting properties to a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-(epoxycyclohexyl)ethyltrimethoxysilane, and the like and may be used alone or in a mixture of two or more.

The silane-based coupling agent may be included in an amount of 0.01 part by weight to parts by weight based on 100 parts by weight of the photosensitive resin composition. When the silane-based coupling agent is included within the above range, close contacting properties, storability, and the like are excellent.

In addition, the photosensitive resin composition may further include a surfactant, such as a fluorine-based surfactant, to improve coating properties and prevent defect formation, if necessary.

The fluorine-based surfactant may include a commercial fluorene-based surfactant, for example, BM-1000®, BM-1100®, and the like of BM Chemie Inc.; MEGAFACE F 142D®, MEGAFACE F 172®, MEGAFACE F 173®, MEGAFACE F 183®, and the like of Dainippon Ink Kagaku Kogyo Co., Ltd.; FULORAD FC-135®, FULORAD FC-170C®, FULORAD FC-430®, FULORAD FC-431® and the like of Sumitomo 3M Co., Ltd.; SURFLON S-112°, SURFLON S-113®, SURFLON S-131®, SURFLON S-141®, SURFLON S-145® and the like of ASAHI Glass Co., Ltd.; SH-28PA®, SH-190®, SH-193®, SZ-6032®, SF-8428®, and the like of Toray Silicone Co., Ltd.; or F-482, F-484, F-478, F-554, and the like of DIC Co., Ltd.

The fluorine-based surfactant may be included in an amount of 0.001 parts by weight to 5 parts by weight based on 100 parts by weight of the photosensitive resin composition. When the fluorine-based surfactant is included within the range, coating uniformity may be ensured, stains are not generated, and wetting properties for a glass substrate are improved.

In addition, a certain amount of other additives such as an antioxidant and a stabilizer may be further added to the photosensitive resin composition within a range that does not impair physical properties.

According to another embodiment, a photosensitive resin film manufactured using the photosensitive resin composition according to the embodiment is provided.

Pattern forming processes in the photosensitive resin film are as follows.

The process includes coating the photosensitive resin composition on a support substrate in a method of spin coating, slit coating, inkjet printing, and the like; drying the coated photosensitive resin composition to form a photosensitive resin composition layer; exposing the photosensitive resin composition layer to light; developing the exposed photosensitive resin composition layer in an alkali aqueous solution to obtain a photosensitive resin film; and heat-treating the photosensitive resin film. Conditions for the patterning process are well known in a related art and will not be illustrated in detail in the specification.

According to another embodiment, a color filter including the photosensitive resin film is provided.

According to another embodiment, a display device including the color filter is provided.

Hereinafter, the present invention is illustrated in more detail with reference to examples, but these examples, however, are not in any sense to be interpreted as limiting the scope of the invention.

### EXAMPLES

### (Synthesis of Photosensitive Resin Compositions)

### Examples 1 to 6 and Comparative Examples 1 to 13

Photosensitive resin compositions according to Examples 1 to 6 and Comparative Examples 1 to 13 were prepared by mixing the components mentioned below in the compositions shown in Table 1.

Specifically, a photopolymerization initiator was dissolved in a solvent and then, stirred for 2 hours at room temperature, and a binder resin and a photopolymerizable compound were added thereto and then, stirred for 2 hours at room temperature. Then, a colorant, a thiol-based compound, a silane coupling agent, and other additive were added to the obtained reactant and then, stirred for 2 hours at room temperature. Then, a product therefrom was three times filtered to remove impurities and prepare a photosensitive resin composition.

TABLE 1
(unit: wt %)

| | | | | | | | | Comp. | Comp. | Comp. | Comp. | Comp. |
|---|---|---|---|---|---|---|---|---|---|---|---|---|
| | | Ex. 1 | Ex. 2 | Ex. 3 | Ex. 4 | Ex. 5 | Ex. 6 | Ex. 1 | Ex. 2 | Ex. 3 | Ex. 4 | Ex. 5 |
| (A) | | 10.65 | 11.11 | 10.65 | 10.65 | 10.65 | 10.65 | 11.00 | 10.83 | 10.90 | 10.90 | 10.90 |
| Binder resin | | | | | | | | | | | | |
| (B) | | 4.26 | 4.45 | 4.26 | 4.26 | 4.26 | 4.26 | 4.40 | 4.34 | 4.37 | 4.37 | 4.37 |
| Photopolymerizable | | | | | | | | | | | | |
| compound | | | | | | | | | | | | |
| (C) | | 1.21 | 0.68 | 1.21 | 1.21 | 1.21 | 1.21 | 1.25 | 1.23 | 1.24 | 1.24 | 1.24 |
| Photopolymerization | | | | | | | | | | | | |
| initiator | | | | | | | | | | | | |
| (D) | (D-1) | 25.90 | 25.90 | 25.90 | 25.90 | 25.90 | 25.90 | 25.90 | 25.90 | 25.90 | 25.90 | 25.90 |
| Colorant | (D-2) | 5.35 | 5.35 | 5.35 | 5.35 | 5.35 | 5.35 | 5.35 | 5.35 | 5.35 | 5.35 | 5.35 |
| (E) | | 52.29 | 52.02 | 52.37 | 52.22 | 52.19 | 52.34 | 52.08 | 52.18 | 52.14 | 52.14 | 52.14 |
| Solvent | | | | | | | | | | | | |
| (F) | | 0.17 | 0.29 | 0.13 | 0.26 | 0.28 | 0.15 | — | 0.15 | — | — | — |
| Thiol-based | | | | | | | | | | | | |
| compound | | | | | | | | | | | | |
| (G) | (G-1) | 0.17 | 0.18 | 0.13 | 0.13 | 0.14 | 0.15 | — | — | — | — | — |
| Silane | (G-2) | — | — | — | — | — | — | — | — | 0.09 | — | — |
| coupling | (G-3) | — | — | — | — | — | — | — | — | — | 0.09 | — |
| agent | (G-4) | — | — | — | — | — | — | — | — | — | — | 0.09 |
| | (G-5) | — | — | — | — | — | — | — | — | — | — | — |

| | | | | | | | | | | | |
|---|---|---|---|---|---|---|---|---|---|---|---|
| (H) | 0.02 | 0.02 | 0.02 | 0.02 | 0.02 | 0.02 | 0.02 | 0.02 | 0.02 | 0.02 | 0.02 |
| Other additives | | | | | | | | | | | |

| | | Comp. | Comp. | Comp. | Comp. | Comp. | Comp. | Comp. | Comp. |
|---|---|---|---|---|---|---|---|---|---|
| | | Ex. 6 | Ex. 7 | Ex. 8 | Ex. 9 | Ex. 10 | Ex. 11 | Ex. 12 | Ex. 13 |
| (A) | | 10.90 | 10.90 | 10.81 | 10.62 | 10.06 | 10.56 | 10.56 | 10.56 |
| Binder resin | | | | | | | | | |
| (B) | | 4.37 | 4.37 | 4.33 | 4.26 | 4.03 | 4.26 | 4.26 | 4.26 |
| Photopolymerizable | | | | | | | | | |
| compound | | | | | | | | | |
| (C) | | 1.24 | 1.24 | 1.23 | 1.21 | 1.76 | 1.21 | 1.21 | 1.21 |
| Photopolymerization | | | | | | | | | |
| initiator | | | | | | | | | |
| (D) | (D-1) | 25.90 | 25.90 | 25.90 | 25.90 | 25.90 | 25.90 | 25.90 | 25.90 |
| Colorant | (D-2) | 5.35 | 5.35 | 5.35 | 5.35 | 5.35 | 5.35 | 5.35 | 5.35 |
| (E) | | 52.14 | 52.14 | 52.20 | 52.31 | 52.64 | 52.13 | 52.43 | 52.21 |
| Solvent | | | | | | | | | |
| (F) | | — | — | — | — | 0.08 | 0.3 | 0.1 | 0.1 |
| Thiol-based | | | | | | | | | |
| compound | | | | | | | | | |
| (G) | (G-1) | 0.09 | — | 0.17 | 0.34 | 0.17 | 0.2 | 0.09 | 0.32 |
| Silane | (G-2) | — | — | — | — | — | — | — | — |
| coupling | (G-3) | — | — | — | — | — | — | — | — |
| agent | (G-4) | — | — | — | — | — | — | — | — |
| | (G-5) | — | 0.09 | — | — | — | — | — | — |

| | | | | | | | | |
|---|---|---|---|---|---|---|---|---|
| (H) | 0.02 | 0.02 | 0.02 | 0.02 | 0.02 | 0.02 | 0.02 | 0.02 |
| Other additives | | | | | | | | |

(A) Binder Resin

Acrylic binder resin (SP-RY-25, Showadenko Co.)

(B) Photopolymerizable Compound

Dipentaerythritolhexaacrylate (DPHA) (Nippon Kayaku Co. Ltd.)

(C) Photopolymerization Initiator

Oxime-based initiator (Samyang Corp.; SPI03)

(D) Colorant

(A-1) C.I. Pigment Blue 15:6 dispersion (Iridos Co., Ltd.; pigment solid content 10%)

(A-2) Blue-Hybrid blue pigment dispersion (Iridos Co., Ltd.; epsilon blue pigment xanthene-based violet dye)

(E) Solvent

PGMEA (Kyowa Co., Ltd.)

(F) Thiol-Based Compound

Pentaerythritoltetrakis (3-mercaptopropionate) (PEMP-20P, SC Organic Chemical Co.,

(G) Silane Coupling Agent

(G-1) Amino-based silane coupling agent (KBM573, Shin-etsu)

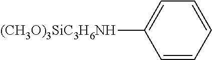

(G-2) Non-amino silane coupling agent (S510, CHISSO Corporation)

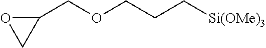

(G-3) Non-amino silane coupling agent (KBM403, Shin-etsu)

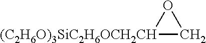

(G-4) Non-amino silane coupling agent (KBM503, Shin-etsu)

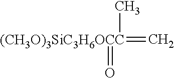

(G-5) Non-amino silane coupling agent (KBM803, Shin-etsu)

(CH₃O)₃SiC₃H₆SH

(H) Additive

Fluorine-based surfactant (F-554, DIC Co., Ltd.)

### (Evaluation)

1. Pattern Characteristics

Each photosensitive resin composition of Example 1 to Example 6, Comparative Example 1 to Comparative Example 13 was coated to be 1 μm to 3 μm thick on a 1 mm-thick degreased and washed glass substrate at 250 rpm to 350 rpm and then, dried on a 90° C. hot plate for 2 minutes to obtain films. Subsequently, the films were exposed to light having a main wavelength of 365 nm with 40 mJ/cm² by using a high-pressure mercury lamp, developed by using a developing solution (prepared by diluting a CD821 solution, Daxin Materials Corp.), and dried in a hot-air circulation drying furnace at 240° C. for 20 minutes.

A completed pattern therefrom was 500 times zoomed in by an optical microscope to measure a size of a 100 μm-wide pattern. Herein, the width size of the pattern was set at 104 μm to 105 μm.

2. Sublimation Characteristics

After forming the pattern, the pattern was treated at 120° C. under humidity of 100% for 1 hour in a PCT equipment and then, 50 times zoomed in by using an optical microscope to check whether or not there were foreign substances around the pattern.

(Evaluation Results)

◯: No sublimable foreign substances

Δ: The pattern of sublimable foreign substances is weakly visible in the surroundings

X: Sublimation foreign substances were widely seen around the pattern

3. Peeling Characteristics

A specimen of the pattern was formed was cut into a size of 4*4, and a 3M tape was adhered thereto and then, inserted into a sus tray filled with water. The tray containing the specimen in the PCT equipment was treated at 115° C. under humidity of 100% for 30 minutes, and after taking the specimen out from the water, the tape was removed therefrom to check whether or not substrate-film were torn away each apart.

(Evaluation Results)

◯: No tearing

Δ: Confirmation of some tearing

X: All tearing

4. Chemical Resistance

After dropping 3 to 4 drops of an NMP solution on the pattern, the specimen was allowed to stand at room temperature for 10 minutes. After the treatment with the solution, an LCF equipment was used to measure a color coordinate and luminance, and color change values therefrom were used to calculate del (E*) and thus to check chemical resistance characteristics.

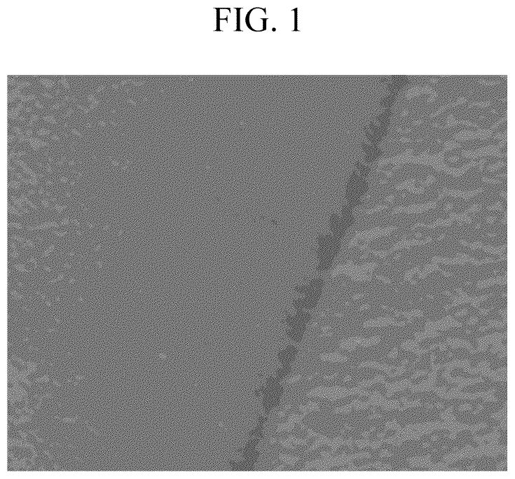

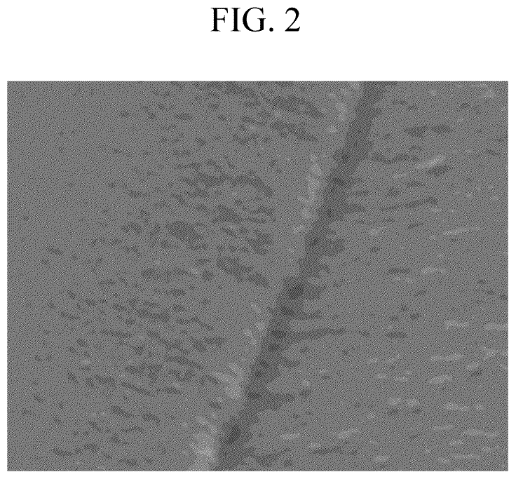

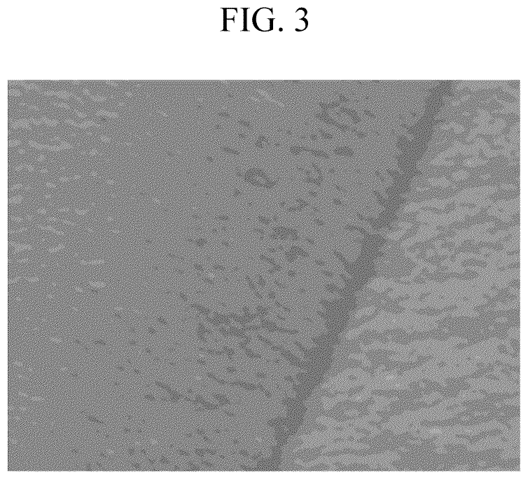

The evaluation results are shown in Table 2 and FIGS. 1 to 3.

TABLE 2

| | Peeling | Sublimation | | | Chemical |
|---|---|---|---|---|---|
| | charac- | charac- | | Pattern | resistance |
| | teristics | teristics | CD | uniformity | (del (E*)) |
| Example 1 | ◯ | ◯ | 104.5 | ◯ | 1.8 |
| Example 2 | ◯ | ◯ | 105.2 | ◯ | 1.2 |
| Example 3 | ◯ | ◯ | 103.8 | ◯ | 2.1 |
| Example 4 | ◯ | ◯ | 105.5 | ◯ | 1.8 |
| Example 5 | ◯ | ◯ | 105.5 | ◯ | 1.7 |
| Example 6 | ◯ | ◯ | 104.4 | ◯ | 1.9 |
| Comparative | X | X | 104.5 | ◯ | 1.7 |
| Example 1 | | | | | |
| Comparative | X | X | 110.2 | X | 1.1 |
| Example 2 | | | | | |
| Comparative | Δ | X | 103.8 | ◯ | 1.8 |
| Example 3 | | | | | |
| Comparative | Δ | X | 103.5 | ◯ | 2.1 |
| Example 4 | | | | | |
| Comparative | X | X | 103.8 | ◯ | 1.9 |
| Example 5 | | | | | |
| Comparative | Δ | ◯ | 101.5 | ◯ | 2.5 |
| Example 6 | | | | | |
| Comparative | X | X | 102.5 | ◯ | 1.8 |
| Example 7 | | | | | |
| Comparative | ◯ | ◯ | 99.7 | ◯ | 2.9 |
| Example 8 | | | | | |
| Comparative | ◯ | ◯ | 92.5 | ◯ | 3.4 |
| Example 9 | | | | | |
| Comparative | ◯ | ◯ | 101.7 | ◯ | 2.1 |
| Example 10 | | | | | |
| Comparative | ◯ | ◯ | 106.2 | X | 1.5 |
| Example 11 | | | | | |
| Comparative | Δ | ◯ | 104.2 | ◯ | 2.2 |
| Example 12 | | | | | |
| Comparative | ◯ | ◯ | 100.5 | ◯ | 2.7 |
| Example 13 | | | | | |

Referring to Table 2 and FIGS. 1 to 3, since the photosensitive resin composition according to an embodiment included an amino-based silane coupling agent to solve the sublimable foreign substances and peeling issues in a high-temperature and high-humidity environment, but even though the use of the amino-based silane coupling agent caused problems of a decrease of CD sensitivity and deterioration of chemical resistance, the decrease of CD sensitivity was improved by controlling a content of the amino-based silane coupling agent, while simultaneously, using a thiol-based compound as an amplifying agent, and in addition, uniformity (pattern properties) of a pattern edge portion was secured by controlling a content of the thiol-based compound.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

1. A photosensitive resin composition, comprising:
a binder resin;
a photopolymerizable compound;
a photopolymerization initiator;
a colorant including a blue pigment;
a solvent;
a thiol compound; and
a silane coupling agent;
wherein the thiol compound and the silane coupling agent are each independently included in an amount of greater than or equal to 0.1 wt % and less than 0.3 wt %, based on based on a total weight of the photosensitive resin composition.

2. The photosensitive resin composition of claim 1, wherein the thiol compound and the silane coupling agent are included in a weight ratio of 1:1 to 2:1.

3. The photosensitive resin composition of claim 1, wherein:
the thiol compound includes at least two functional groups represented by Chemical Formula 1 at a terminal end: 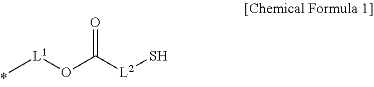
in Chemical Formula 1, L¹ and L² are each independently a single bond, a substituted or unsubstituted C1 to C20 alkylene group, a substituted or unsubstituted C3 to C20 cycloalkylene group, a substituted or unsubstituted C6 to C20 arylene group, or a substituted or unsubstituted C2 to C20 heteroarylene group.

4. The photosensitive resin composition of claim 3, wherein:
the thiol compound is represented by Chemical Formula 1-1: 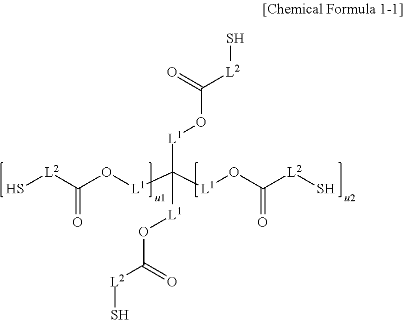
in Chemical Formula 1-1,
L¹ and L² are each independently a single bond, a substituted or unsubstituted C1 to C20 alkylene group, a substituted or unsubstituted C3 to C20 cycloalkylene group, a substituted or unsubstituted C6 to C20 arylene group, or a substituted or unsubstituted C2 to C20 heteroarylene group, and
u1 and u2 are each independently 0 or 1.

5. The photosensitive resin composition of claim 1, wherein the silane coupling agent is an amino silane coupling agent.

6. The photosensitive resin composition of claim 5, wherein:
the amino silane coupling agent is represented by Chemical Formula 2: 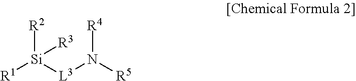
in Chemical Formula 2,
R¹ to R³ are each independently a hydrogen atom, a substituted or unsubstituted C1 to C20 alkyl group, or a substituted or unsubstituted C1 to C20 alkoxy group,
R⁴ and R⁵ are each independently a hydrogen atom, a substituted or unsubstituted C1 to C20 alkyl group, or a substituted or unsubstituted C6 to C20 aryl group, and
L³ is a substituted or unsubstituted C1 to C20 alkylene group.

7. The photosensitive resin composition of claim 1, wherein the binder resin includes an acrylic binder resin, a cardo binder resin, or a combination thereof.

8. The photosensitive resin composition of claim 7, wherein:
the binder resin includes the acrylic binder resin, and
the acrylic binder resin has a weight average molecular weight of 5000 g/mol to 15000 g/mol.

9. The photosensitive resin composition of claim 7, wherein:
the binder resin includes the acrylic binder resin, and
the acrylic binder resin has an acid value of 80 mgKOH/g to 130 mgKOH/g.

10. The photosensitive resin composition of claim 1, wherein the photosensitive resin composition includes:
5 wt % to 20 wt % of the binder resin;
1 wt % to 10 wt % of the photopolymerizable compound;
0.1 wt % to 10 wt % of the photopolymerization initiator;
5 wt % to 50 wt % of the colorant;
30 wt % to 70 wt % of the solvent;
0.1 wt % to 0.29 wt % of the thiol compound; and
0.1 wt % to 0.29 wt % of the silane coupling agent, based on the total weight of the photosensitive resin composition.

11. The photosensitive resin composition of claim 1, wherein the photosensitive resin composition includes malonic acid; 3-amino-1,2-propanediol; a leveling agent; a fluorine surfactant; or a combination thereof.

12. A photosensitive resin film manufactured using the photosensitive resin composition of claim 1.

13. A color filter comprising the photosensitive resin film of claim 12.

14. A display device comprising the color filter of claim 13.
